(19) United States
(12) Patent Application Publication
(10) Pub. No.: US 2015/0034376 A1
(43) Pub. Date: Feb. 5, 2015

(54) PRINTED CIRCUIT BOARD STRUCTURE

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventor: TAO WANG, Shenzhen (CN)

(73) Assignees: HON HAI PRECISION INDUSTRY CO., LTD., New Taipei (TW); HONG FU JIN PRECISION INDUSTRY (ShenZhen) CO., LTD, Shenzhen (CN)

(21) Appl. No.: 14/152,988

(22) Filed: Jan. 10, 2014

(30) Foreign Application Priority Data
Jul. 30, 2013 (CN) 2013103237673

(51) Int. Cl. H05K 1/11

(52) U.S. Cl. CPC H05K 1/115
USPC 174/262

(57) ABSTRACT

A printed circuit board (PCB) structure comprises two signal layers with and a ground layer sandwiched between the two signal layers, and at least two adjacent vias. Each of the signal layers comprises a plurality of signal traces. The via through the PCB structure is used for connecting signal traces on different signal layers together. The ground layer comprises at least one insulation region. Each of the vias comprises at least two pads and a connecting portion connecting the at least two pads together. The pads are respectively mounted on the at least two signal layer. Projections of the adjacent pads on the ground layer are contained in the same insulation region.

### TECHNICAL FIELD

The present disclosure relates to printed circuit board (PCB) structure.

### DESCRIPTION OF RELATED ART

A printed circuit board (PCB) structure includes a plurality of layers and vias through the PCB structure. The layers include two signal layers and a ground layer sandwiched by the two signal layers. Each of the signal layers includes a plurality of signal traces for transmitting signals. The signal trace on one signal layer connects to the corresponding via for connecting with the signal trance on the other layer. The ground layer further defines an insulation region. The insulation region is concentric with the via for preventing the signals transmitted to the signal layer from transmitting to the ground layer. In normal designed structure, the insulation region is an annulus shaped, and a diameter of the insulation region is unchangeable. A parasitic capacitor exists around the via. A transmission loss in signal transmitting process is related to the area of the insulation region. However, when transmitting high-speed signal, the transmission loss of the PCB structure with the constant diameter of the insulation region is increased.

Therefore, there is room for improvement in the art.

### BRIEF DESCRIPTION OF THE FIGURE

The components of the drawings are not necessarily drawn to scale, the emphasis instead being placed upon clearly illustrating the principles of the embodiment of a printed circuit board (PCB) structure. Moreover, in the drawings, like reference numerals designate corresponding parts throughout several views.

FIG. 1 is a schematic view of one embodiment of a printed circuit board (PCB) structure, the PCB structure including two signal layers and a ground layer.

FIG. 2 is an enlarged partially disassembled view of layers of FIG. 1.

FIG. 3 is a partially cross-sectional view of the ground layer of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.” The references “a plurality of” and “a number of” mean “at least two.” Embodiments of the present disclosure will be described in detail with reference to the drawings.

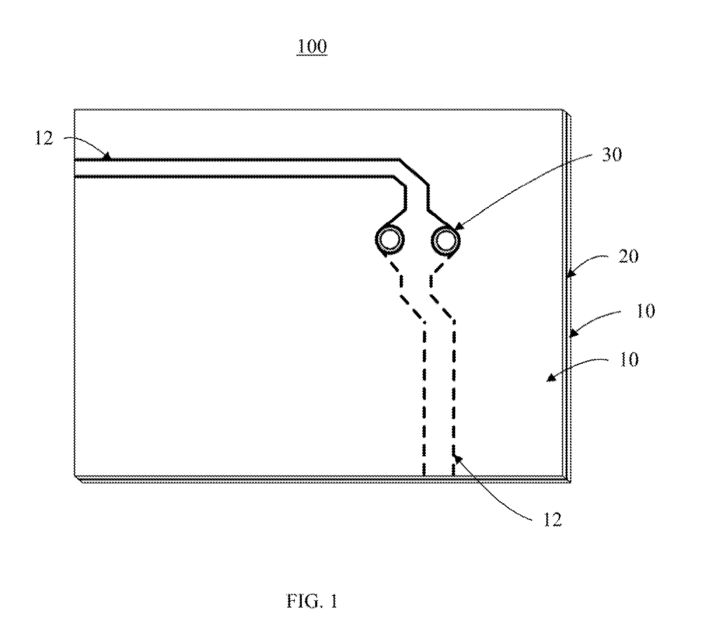

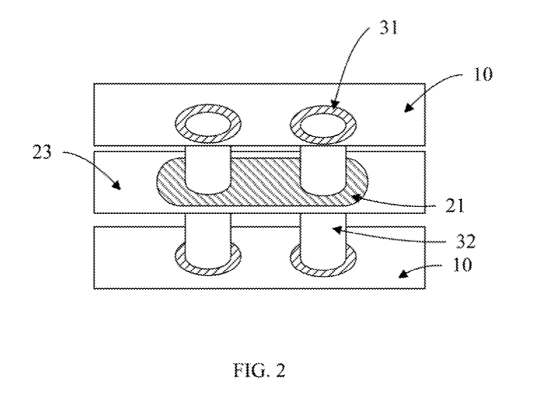

FIGS. 1 and 2 show a printed circuit board (PCB) structure 100 of the embodiment. The PCB structure 100 includes two signal layers 10, a ground layer 20 sandwiched between the two signal layers 10, and at least two adjacent vias 30 through the PCB structure 100. In other embodiments, the PCB structure 100 may include more than two signal layers 10. The via 30 can a buried via or a blind via.

The signal layer 10 includes a plurality of signal traces 12. The signal traces 12 are used for transmitting signals. The signal traces 12 on the same layer are parallel with each other, and the ends of the parallel signal traces 12 angled with each other are connected to the via 30 for connecting signal traces 12 on the different signal layer 10.

The ground layer 20 is substantially rectangular shaped. The ground layer 20 comprises a plurality of insulation regions 21 corresponding to the vias 30. The region beside the insulation regions 21 is conductive region 23. The insulation region 21 is substantially a round-corner rectangular shaped. The insulation region 21 defines at least two through holes 212 corresponding to the vias 30. In one embodiment, the insulation region 21 is filled with insulation material, and the conductive region 23 is filled with cooper

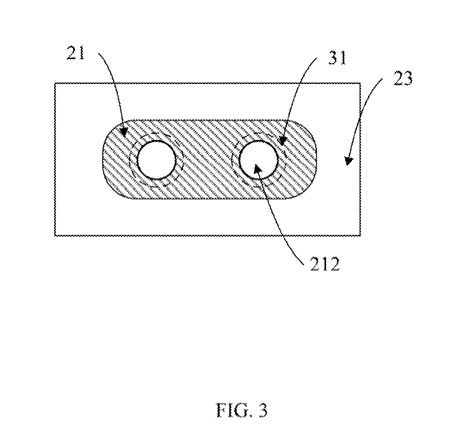

The via 30 includes two pads 31 and a connecting portion 32 through the PCB structure 100. The pads 31 are respectively mounted on the different signal layers 10, and are connected with signal trace 12. The pad 31 is substantially an annulus shaped. Projections of the pads 31 of the adjacent vias 30 on the ground layer 20 are contained in the same insulation region 21 (as shown in FIG. 3), and are respectively concentric with the corresponding through holes 212. A minimum distance between the projection of the pad 31 on the ground layer 20 and the conductive region 23 is larger than a predetermined distance. In one embodiment, the predetermined distance is 3 mil.

The connecting portion 32 is substantially cylinder shaped. The connecting portion 32 is used for connecting the two pads 31 together, and is concentric with the through hole 212. The diameter of the connecting portion 32 is equal to the diameter of the through hole 212. In one embodiment, the connecting portion 32 is made of conductive material.

In summary, the pads 31 on the same signal layer 10 of the adjacent vias 30 correspond to the same insulation region 21 on the ground layer 20, such that, the insulation area corresponding to each of the vias 30 is increased, and when transmitting high-speed signal the transmission loss in the signal transmitting process is decreased.

While various exemplary and preferred embodiments have been described, the disclosure is not limited thereto. On the contrary, various modifications and similar arrangements (as would be apparent to those skilled in the art) are intended to also be covered. Therefore, the scope of the appended claims should be accorded the broadest interpretation so as to encompass all such modifications and similar arrangements.

What is claimed is:

1. A printed circuit board (PCB) structure, comprising:
at least two signal layers with a plurality of signal traces;
a ground layer sandwiched between the at least two signal layers; and
at least two adjacent vias through the PCB structure, and for connecting signal traces on different signal layers together;
wherein the ground layer comprises at least one insulation region; each of the vias comprises at least two pads and a connecting portion connecting the at least two pads together; the pads respectively mounted on the at least two signal layer; projections of the adjacent pads on the ground layer are contained in the same insulation region.

2. The PCB structure of claim 1, wherein the ground layer further comprises a conductive region beside the insulation region; a minimum distance between the projection of the pad on the ground layer and the conductive region is larger than a predetermined distance.

3. The PCB structure of claim 2, wherein the predetermined distance is 3 mil.

4. The PCB structure of claim 1, wherein the projection of the pad on the ground layer is concentric with the connecting portion.

5. The PCB structure of claim 1, wherein the insulation region is substantially a round-corner rectangular shaped.
